(19) United States
(12) Patent Application Publication
(10) Pub. No.: US 2026/0024610 A1
(43) Pub. Date: Jan. 22, 2026

(54) MEMORY DEVICE

(71) Applicant: AP Memory Technology Corporation, Hsinchu County (TW)

(72) Inventor: WenLiang Chen, HsinChu (TW)

(73) Assignee: AP Memory Technology Corporation, Hsinchu County (TW)

(21) Appl. No.: 18/988,829

(22) Filed: Dec. 19, 2024

Related U.S. Application Data
(60) Provisional application No. 63/672,268, filed on Jul. 17, 2024.

(51) Int. Cl. G11C 29/52; G11C 11/4094; G11C 11/4096

(52) U.S. Cl. CPC G11C 29/52; G11C 11/4094; G11C 11/4096

(57) ABSTRACT

A memory device includes a first bit line set, a first column selection circuit, a first data line and a second data line. The first bit line set includes a first bit line and a second bit line. The first column selection circuit is coupled to the first bit line and the second bit line. The first data line includes a first line segment coupled to the first column selection circuit. The second data line includes a second line segment coupled to the first column selection circuit. Wherein the first column selection circuit is configured to electrically connect the first bit line to the first line segment for transmitting a first bit of normal data to the first line segment, and to electrically connect the second bit line to the second line segment for transmitting a first bit of Error Correction/Detection data to the second line segment.

### CROSS-REFERENCE TO RELATED APPLICATION

This application claims the priority benefit of U.S. provisional application Ser. No. 63/672,268, filed on Jul. 17, 2024. The entirety of the above-mentioned patent application is hereby incorporated by reference herein and made a part of this specification.

### BACKGROUND

### Technical Field

The present application generally relates to a memory device, and more particularly to the memory device which can provide extra bits by enhanced I/O bandwidth.

### Description of Related Art

Dynamic random-access memory (DRAM) is widely used as a computer's main memory

because of its cost-effectiveness. A DRAM device includes a plurality of memory cells, each of which can store a data bit and is usually implemented using a capacitor and a transistor. The capacitor can be charged or discharged to represent a value of the data bit stored in the memory cell. For example, an empty capacitor can denote a logical value of 0, and a fully charged capacitor can denote a logical value of 1. As the technology nodes shrinks, the memory cell gets smaller and the capacitor will store a very limited amount of charge. To provide data that can be interpreted properly, the DRAM device utilizes a sense amplifier to produce an output in the form of recognizable logic levels.

### SUMMARY

The present application provides memory devices which can provide extra bits by enhanced I/O bandwidth.

The memory device includes a first bit line set, a first column selection circuit, a first data line and a second data line. The first bit line set includes a first bit line and a second bit line. The first column selection circuit is coupled to the first bit line and the second bit line. The first data line includes a first line segment coupled to the first column selection circuit. The second data line includes a second line segment coupled to the first column selection circuit. Wherein the first column selection circuit is configured to electrically connect the first bit line to the first line segment for transmitting a first bit of normal data to the first line segment, and to electrically connect the second bit line to the second line segment for transmitting a first bit of Error Correction/Detection data to the second line segment.

Another memory device includes a plurality of memory cell arrays and a plurality of data sensing circuitry areas. Each of the data sensing circuitry areas is disposed between two of the adjacent memory cell arrays, each of the data sensing circuitry areas includes a main space and an extended space. The main space has a plurality of I/O pads for outputting a normal storage data during a normal data reading operation. The extended space is disposed in adjacent to the main space, and has a plurality of extended I/O pads for outputting an ECC data during an ECC data reading operation. Wherein at least a first bit of the normal storage data is generated from the extended space during the normal data reading operation.

In summary, the memory devices of present embodiments provide a segmented data line structure, and can transmit extra bits through at least one extra line segment of data line. In present embodiments, the extra bits can be provided to be error correction/detection codes to improve data reliability of the memory device.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a diagram illustrating a partial physical implementation of a memory device in accordance with some embodiments.

FIG. 2 illustrates a schematic diagram of a portion of a memory device according to an embodiment of present disclosure.

FIG. 3A and FIG. 3B illustrate schematic diagrams of a portion of a memory device according to another embodiment of present disclosure.

FIG. 4 illustrates a schematic diagram of a portion of a memory device according to an embodiment of present disclosure.

FIG. 5 is a diagram illustrating a portion of a memory device according to an embodiment of present disclosure.

FIG. 6 is a diagram illustrating a portion of a memory device according to an embodiment of present disclosure.

FIG. 7 illustrates a schematic diagram of a semiconductor device according to an embodiment of present application.

FIG. 8 illustrates a block diagram of a semiconductor device according to an embodiment of present disclosure.

### DESCRIPTION OF THE EMBODIMENTS

Reference will now be made in detail to the present preferred embodiment of the invention, examples of which are illustrated in the accompanying drawings. Wherever possible, the same reference numbers are used in the drawings and the description to refer to the same or like parts.

A detailed description of embodiments of the present invention is provided with reference to the Figures. It is to be understood that there is no intention to limit the technology to the specifically disclosed structural embodiments and methods but that the technology may be practiced using other features, elements, methods and embodiments. Preferred embodiments are described to illustrate the present technology, not to limit its scope, which is defined by the claims. Those of ordinary skill in the art will recognize a variety of equivalent variations on the description that follows.

As used herein, the term “coupled” means operatively coupled. Items that are coupled in this sense are not necessarily directly connected, and there may be intervening items between the coupled items.

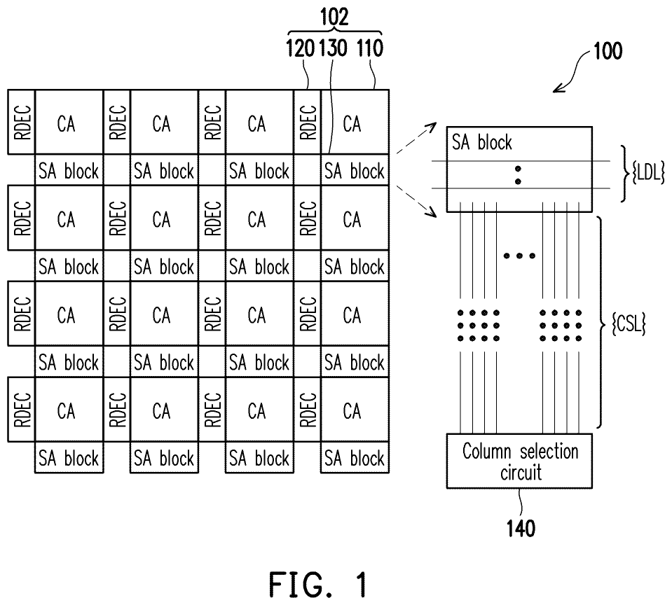

Please refer to FIG. 1, which is a diagram illustrating a partial physical implementation of a memory device in accordance with some embodiments. In FIG. 1, the memory device 100 can be implemented as a dynamic random access memory (DRAM) bank, which includes a plurality of tiles 102 arranged in an array. Each of the tiles 102, also referred to as a memory array tile (MAT), may include a cell array (CA) 110, a row decoder (RDEC) 120 and a sense amplifier (SA) block 130. The cell array 110 includes a plurality of storage cells arranged in rows and columns. Storage cells in a given row share a common word line (not shown) extending in a row direction; storage cells in a given column are coupled to a same bit line (not shown) extending in a column direction. The row decoder 120 is arranged and configure to activate word lines. There are a plurality of sense amplifiers disposed in the sense amplifier blocks 130. The sense amplifier block 130 is arranged to sense and amplify data signals on bit lines, and provide sensed signals to corresponding data lines.

The memory device 100 may be implemented using, but is not limited to, open bit line architecture. For example, in a given row of the cell array 110, a part of storage cells arranged in the row is coupled to one sense amplifier block on the top of the cell array 110 through a part of the bit lines, and another part of the storage cells is coupled to another sense amplifier block on the bottom of the cell array 110 through another part of the bit lines.

The memory device 100 may further include a column selection circuit 140, which is arranged to select sense amplifiers from a sense amplifier block and couple the selected sense amplifiers to a set of data lines. For example, each bit line arranged in the cell array 110 is coupled to an associated sense amplifier of the sense amplifier block 130. The column selection circuit 140 can be configured to activate a column select line in a set of column select lines {CSL} to thereby select a bit line set arranged in the cell array 110, and accordingly couple the selected bit line set to a data line set {LDL}. Each of the data lines in the data line set {LDL} can be shared across multiple columns of storage cells in the cell array 110. It should be noted that the memory device 100 may be implemented to have a hierarchical structure, in which the data line set {LDL} may be referred to as a set of local data lines that is coupled to a set of global data lines (not shown) arranged along the column direction.

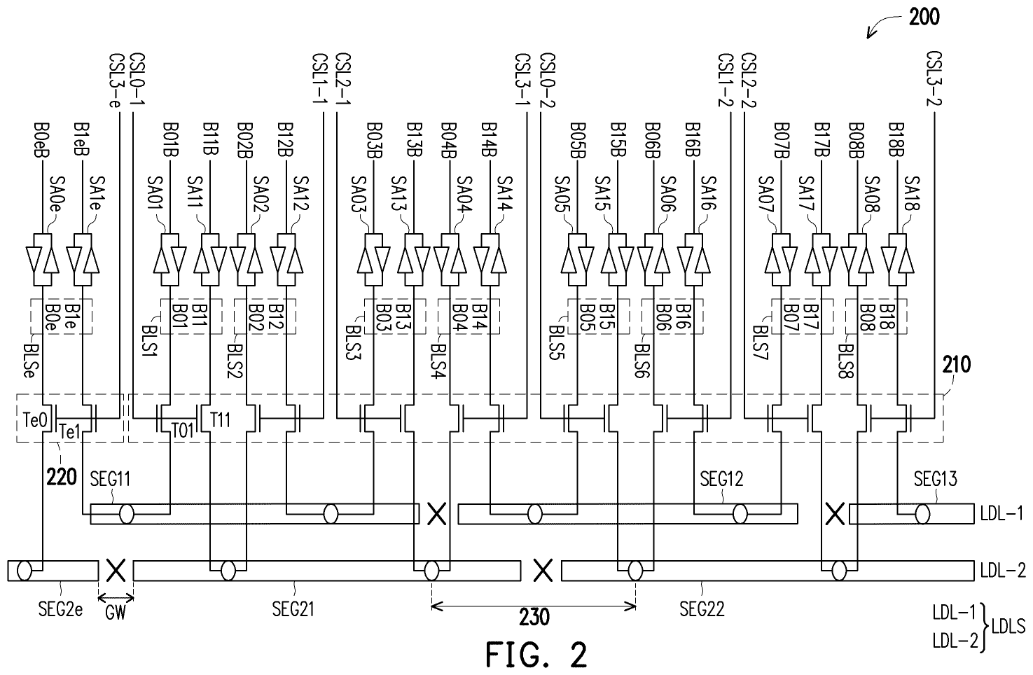

Please refer to FIG. 2, which illustrate a schematic diagram of a portion of a memory device according to an embodiment of present disclosure. The portion of the memory device 200 in FIG. 2 may correspond to sense amplifier block 130 in FIG. 1. The memory device 200 includes a plurality of bit line sets BLSe, BLS1 to BLS8, a set of data lines LDLS, a column selection circuit 210 and an extra column selection circuit 220. In this embodiment, the bit line sets BLSe include bit lines B0e and B1e, the bit line sets BLS1 to BLS8 respectively include bit lines B01, B11 to B08, B18. The bit line sets BLSe is an extra bit line set in comparison to the counterpart of the existing memory device. More specifically, at least two technical effects may be obtained from the bit line sets BLSe, one is to address the issues caused by the segmentation of data line set {LDL}, and the other is to provide error correction/detection code (ECC) data for the memory device 200. The detailed description of the bit line sets BLSe will be described in the following paragraphs.

The bit line sets BLSe corresponds to a plurality of sense amplifiers SA0e and SA1e, and the bit line sets BLS1 to BLS8 respectively correspond to a plurality of sense amplifiers SA01, SA11 to SA08, SA18. The sense amplifiers SA0e and SA1e are respectively further coupled to complementary bit lines B0eB and B1eB, the sense amplifiers SA01, SA11 to SA08, SA18 are respectively further coupled to complementary bit lines B01B, B11B to B08B, B18B. For brevity, the bit lines B0eB, B1eB, B01B, B11B to B08B, B18B as well as the bit lines in another embodiments may also be regarded as the data bits of the memory device as these bit lines are electrically connected to the storage units of the memory device. In this embodiment, the signals on the bit lines B0e, B1e and B01 to B18 may be inverted to the signals on the complementary bit lines B0eB, B1eB and B01B to B18B, respectively. In this embodiment, structure of each of the sense amplifiers SA0e, SA1e, SA01, SA11 to SA08 to SA18 may the same and can be implemented by any sense amplifying circuit well known by a person skilled in this art.

The column selection circuit 210 includes a plurality of switches formed by transistors. Each of the switches correspond to each of the bit lines B01 to B18, and is configured to couple corresponding bit line to a data line. Two of the adjacent switches in the column selection circuit 210 form a switch pair. Control ends of the switch pairs are respectively coupled to column selection lines CSL0-1 to CSL3-2.

For example, in the column selection circuit 210, transistors T01 and T11 forms two switches, and the transistor T01 is coupled between the bit line B01 and a line segment SEG11 of a data line LDL-1. The transistor T11 is coupled between the bit line B11 and a line segment SEG21 of a data line LDL-2. Controls ends of the transistors T10 and T11 are coupled to the same column selection line CSL0-1, and have same turn-on or cut-off status according to a column selection signal on the column selection line CSL0-1. In detail, when the switch formed by the transistor T01 is turned-on, the bit line B01 is coupled to the line segment SEG11 of a data line LDL-1, and when the switch formed by the transistor T11 is turned-on, the bit line B11 is coupled to the line segment SEG21 of a data line LDL-2.

In this embodiment, the bit line sets BLS1 to BLS4 may be group into a first bit line group, and the bit line sets BLS5 to BLS8 may be group into a second bit line group. The column selection lines CSL0-1 to CSL3-1 may be correspond to the first bit line group, and the column selection lines CSL0-2 to CSL3-2 may be correspond to the second bit line group. During the operation, in the first bit line group, one of the column selection lines CSL0-1 to CSL3-1 may be activated to turn on the corresponding switches, and others of the column selection lines CSL0-1 to CSL3-1 are deactivated. Also, in the second bit line group, one of the column selection lines CSL0-2 to CSL3-2 may be activated to turn on the corresponding switches at a same time, and others of the column selection lines CSL0-2 to CSL3-2 are deactivated. In this embodiment, the column selection line CSL0-1 corresponded to the first bit line group and the column selection line CSL0-2 corresponded to the second bit line group are activated by a same column selection signal CSL0, in which the column selection signal CSL0 may comprise CSL0-1 and CSL0-2. The column selection line CSL1-1 corresponded to the first bit line group and the column selection line CSL1-2 corresponded to the second bit line group are activated by a same column selection signal CSL1, in which the column selection signal CSL1 may comprise CSL1-1 and CSL1-2. The column selection line CSL2-1 corresponded to the first bit line group and the column selection line CSL2-2 corresponded to the second bit line group are activated by a same column selection signal CSL2, in which the column selection signal CSL2 may comprise CSL2-1 and CSL2-2. The column selection line CSL3-1 corresponded to the first bit line group and the second bit line group, and the column selection line CSL3-2 corresponded to the second bit line group and the third bit line group (not shown). The column selection lines CSL3-1 and CSL3-2 may be activated by a same column selection signal CSL3, in which the column selection signal CSL3 may comprise CSL3-1, CSL3-e, and CSL3-2.

In this embodiment, the data line LDL-1 may be divided into a plurality of line segments SEG11 to SEG13. The data line LDL-2 may be divided into a plurality line segments SEG21 to SEG22 and an extra line segment SEG2e in comparison to the counterpart of the existing memory device. Each of the line segments SEG11 to SEG13 may be configured to transmit a first data, and each of the segments SEG21 to SEG22 may be configured to transmit a second data. Furthermore, the extra line segment SEG2e may be configured to transmit an extra bit in addition to the first data and the second data. In this embodiment, in the data line LDL-1, the adjacent line segments SEG11 and SEG12 is isolated by a gap X, and the adjacent line segments SEG12 and SEG13 is isolated by another gap X. Also, in the data line LDL-2, the adjacent line segments SEG2e and SEG21 is isolated by a gap X, and the adjacent line segments SEG21 and SEG22 is isolated by another gap, too. In some of the embodiments, a width GW of the segment is within 1 μm. This dimension is fit for implement in the local data line (LDL) design, then higher density LDL segments can be achieved. In some of the embodiments, the pitch 230 between two adjacent vias on the LDL segments is about 1.1 μm, and a width GW of the gap X within 1 μm can be introduced in a mask design for the LDL, so the dimension of the gap X and the density of LDL segments can be well controlled. In some of the embodiments, the implementation of gaps X on the data lines do not cause the wasted space in the sense amplifier block, and there is no requirement to place dummy patterns in the sense amplifier block or cell array.

The extra column selection circuit 220 includes switched respectively formed by transistors Te0 and Te1. The transistor Te0 is coupled between the bit line B0e and an extra line segment SEG2e of the data line LDL-2. The transistor Te1 is coupled between the bit line B1eand the line segment SEG11 of the data line LDL-1. The transistors Te0 and Te1 are commonly controlled by a column selection signal CSL3 on a column selection line CSL3-e. When the column selection signal CSL3 on the column selection line CSL3-e is activated, the switched formed by the transistors Te0 and Te1 are turned on, and the bit line B0e may be coupled to the extra line segment SEG2e of the data line LDL-2, and the bit line B1e may be coupled to the line segment SEG11 of the data line LDL-1. It can be seen that, the extra line segment SEG2e of the data line LDL-2 can be configured to provide or receive an extra bit generated by the sense amplifier SA0e.

In this embodiment, in detail, a line segment configured to receive four bits corresponding to the column selection signals CSL0-1 to CSL3-1 or the column selection signals CSL0-2 to CSL3-2 is a complete bit segment. For example, the line segment SEG11 includes four addressable bits reading from the bit line B01 selected by the column selection signals CLS0-1; the bit line B12 selected by the column selection signal CSL1-1; the bit line B03 selected by the column selection signal CSL2-1 and the bit line Ble selected by the column selection signal CSL3-e. Likewise, the line segment SEG21 includes four addressable bits reading from bit line B11 selected by the column selection signal CLS0-1; the bit line B02 selected by the column selection signal CSL1-1; the bit line B13 selected by the column selection signal CSL2-1 and the bit line B04 selected by the column selection signal CSL3-1. Following the same way, the line segment SEG12 and the line segment SEG22 are complete bit segments as well.

In this embodiment, in detail, the extra line segment SEG2e is incomplete bit segment. For brevity, the line segment SEG13 may also be regarded as incomplete bit segment. During the operation, when one of the column selection signals CSL0, CSL1, CSL2 is activated, the corresponding data are outputted on the line segments SEG11 and SEG21, and there is no bit exist on the extra line segment SEG2e. When the column selection signal CSL3 is activated, not only the corresponding data are outputted on the line segments SEG11 (i.e. the bit reading from bit line B1e) and SEG21 (i.e. the bit reading from bit line B04), the extra line segment SEG2e also includes one addressable bit reading from bit line B0e selected by the column selection signal CSL3-e. On the other hand, when one of the column selection signals CSL0, CSL1, CSL2 is activated, the corresponding data are outputted on the line segments SEG12 and SEG22, and there is no bit exist on the extra line segment SEG13. When the column selection signal CSL3 is activated, not only the corresponding data are outputted on the line segments SEG12 (i.e. the bit reading from bit line B14) and SEG22 (i.e. the bit reading from bit line B08), the line segment SEG13 also includes one addressable bit reading from bit line B18 selected by the column selection signal CSL3-2. Therefore, the addressable bits on the extra line segment SEG2e and the line segment SEG13 may be regarded as extra bits during the read operation of the memory device 200.

Accordingly, in this embodiment, the bits on the line segments SEG11, SEG12, SEG21 and SEG22 are main bits represent the storage of the memory device 200. The bits on the line segments SEG2e and SEG13 are the extra bits in addition to the normal storage data. According to the present disclosure, the extra bit may be provided to be error correction/detection code, such as ECC data or any other error correction/detection information. Number of extra bits for ECC correction can be modulated by increasing the extra line segments, extra column selection lines and extra sense amplifiers. The more extra bits can perform error correction/detection with higher level.

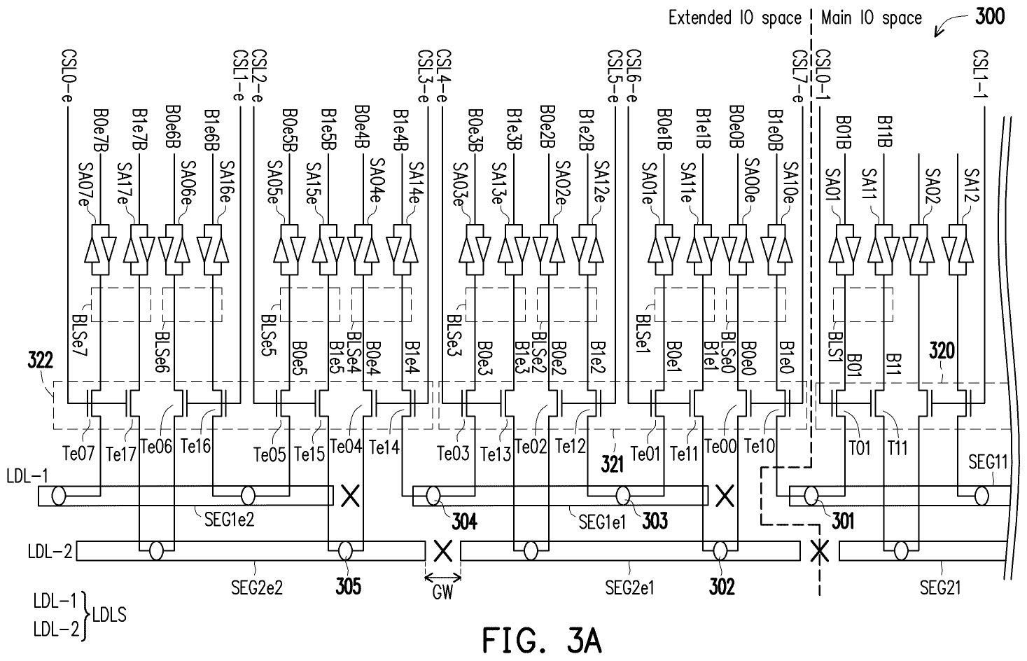

Please refer to FIG. 3A, which illustrates a schematic diagram of a portion of a memory device according to another embodiment of present disclosure. The portion of the memory device 300 in FIG. 3A may also correspond to sense amplifier block 130 in FIG. 1. Moreover, in this embodiment, different from the embodiment in FIG. 2, number of extra bits can be extended by setting more extra bit line sets. For brevity, the detailed description of the extra bit on the line segment SEG13 in FIG. 2 is omitted in following paragraph.

In FIG. 3A, the memory device 300 includes extra bit line sets BLse0 to BLse7. Each of the extra bit line sets BLse0 to BLse7 includes two bit lines. For example, the extra bit line set BLse0 includes bit lines B1e0 and B0e0, the extra bit line set BLse1 includes bit lines B1e1 and B0e1, and so on. The extra bit line sets BLse0 to BLse7 respectively correspond to sense amplifiers SA10e, SA00e to SA17e and SA07e. The sense amplifiers SA10e, SA00e to SA17e and SA07e are respectively further coupled to complementary bit lines B1e0B, B0e0B to B1e7B and B0e7B. The extra column selection circuits 321 and 322 include a plurality of switched formed by transistors Te10, Te00 to Te17 and Te07, respectively. Furthermore, the data line LDL-1 in this embodiment further includes extra line segments SEG1e1 and SEG1e2, the data line LDL-2 in this embodiment further includes extra line segments SEG2e1 and SEG2e2, wherein a length of the extra line segment SEG2e1 of the second data line LDL-2 is extended to become a complete line segment in comparison to the embodiment as shown in FIG. 2. The extra line segments SEG1e1 and SEG1e2 are isolated by a gap X, and the extra line segments SEG2e1 and SEG2e2 are also isolated by a gap X. A width GW of each gap X between two of the adjacent segments may be within 1 μm. However, this is not a limitation of the present disclosure. The width GW may be adjusted in accordance with the pitch between two adjacent vias on the line segments.

In this embodiment, the bit line set BLS1 includes bit lines B01 and B11. Transistors T01 and T11 are disposed in the column selection circuit 320, the transistor T01 is coupled between the bit line B01 and the line segment SEG11, and the transistor T11 is coupled between the bit line B11 and the line segment SEG21. The transistor T01 is configured to electrically connect the bit line B01 to the line segment SEG11 for transmitting a bit of normal data from the bit line B01 to the line segment SEG11. The transistor T11 is configured to electrically connect the bit line B11 to the line segment SEG21 for transmitting a bit of normal data from the bit line B11 to the line segment SEG21. In some embodiments, the line segment SEG21 and the line segment SEG2e1 are separated by a gap X, wherein the gap X between the line segment SEG11 and the line segment SEG1e1 and the gap X between the line segment SEG21 and the line segment SEG2e1 may form a straight line and the straight line is perpendicular to the data line LDL-1 and the data line LDL-2.

In detail, in the column selection circuit 321, the switch formed by the transistor Te10 is coupled between the sense amplifier SA10e and the line segment SEG11 of the data line LDL-1; the switch formed by the transistor Te00 is coupled between the sense amplifier SA00e and the extra line segment SEG2e1 of the data line LDL-2; the switch formed by the transistor Te11 is coupled between the sense amplifier SA11e and the extra line segment SEG2e1 of the data line LDL-2; the switch formed by the transistor Te01 is coupled between the sense amplifier SA01e and the extra line segment SEG1e1 of the data line LDL-1. Furthermore, the switch formed by the transistor Te12 is coupled between the sense amplifier SA12e and the extra line segment SEG1e1 of the data line LDL-1; the switch formed by the transistor Te02 is coupled between the sense amplifier SA02e and the extra line segment SEG2e1 of the data line LDL-2; the switch formed by the transistor Te13 is coupled between the sense amplifier SA13e and the extra line segment SEG2e1 of the data line LDL-2; and the switch formed by the transistor Te03 is coupled between the sense amplifier SA03e and the extra line segment SEG1e1 of the data line LDL-1.

Furthermore, in the column selection circuit 322, the switch formed by the transistor Te14 is coupled between the sense amplifier SA14e and the extra line segment SEG1e1 of the data line LDL-1; the switch formed by the transistor Te04 is coupled between the sense amplifier SA04e and the extra line segment SEG2e2 of the data line LDL-2; the switch formed by the transistor Te15 is coupled between the sense amplifier SA15e and the extra line segment SEG2e2 of the data line LDL-2; the switch formed by the transistor Te05 is coupled between the sense amplifier SA05e and an extra line segment SEG1e2 of the data line LDL-1. Furthermore, the switch formed by the transistor Te16 is coupled between the sense amplifier SA16e and the extra line segment SEG1e2 of the data line LDL-1; the switch formed by the transistor Te06 is coupled between the sense amplifier SA06e and the extra line segment SEG2e2 of the data line LDL-2; the switch formed by the transistor Te17 is coupled between the sense amplifier SA17e and the extra line segment SEG2e2 of the data line LDL-2; and the switch formed by the transistor Te07 is coupled between the sense amplifier SA07e and the extra line segment SEG1e2 of the data line LDL-1.

According to the present disclosure, the extra line segments SEG1e1, SEG1e2, SEG2e1 and SEG2e2 are configured to transmit extra bits in addition to the normal storage data, and the extra bits may be error correction/detection codes.

In this embodiment, by disposing 8 extra bit line sets BLSe0 to BLSe7, the extra line segment SEG1e1 and SEG1e2 may provide seven extra bits, and the extra line segments SEG2e1 and SEG2e2 may provide eight extra bits, and 15 extra bits can be provided in the memory device 300. In other embodiments, if there are 4 extra bit line sets are disposed, 7 extra bits can be provided in the memory device.

It should be noted here, in other embodiments, number of data lines and extra bit line sets may be adjusted by necessary of users. For example, the number of the data lines may be adjusted to 4, the number of the extra bit line sets may be adjusted to 4, and the bit line groups of the memory device may provide 14 extra bits. By providing 14 extra bits for SECDED (single error correction, double error detection), a codeword including 213 bits can be checked and corrected. In some of the embodiments, the memory device includes n data lines and m extra bit line sets. The number of extra bits can be simplified as (n*m)−(n/2). However, there is no limit thereto. The number of extra bits can be modulated by adding or reducing the number of data line segments or extra bit line sets.

Please refer to FIG. 3B, which illustrates a schematic diagram of a portion of a memory device according to another embodiment of present disclosure. The portion of the memory device 300′ in FIG. 3B is similar to the portion of the memory device 300 in FIG. 3A. Different from the memory device 300, in the memory device 300′, gaps X on the data line LDL-1 are respectively aligned to corresponding gaps X on the data line LDL-2 in a same straight line which is perpendicular to the data line LDL-1 and LDL-2. Such as that, the segments SEG1e2 and

SEG1e1 are respectively aligned with the corresponding segments SEG2e2 and SEG2e. Accordingly, the layout complexity of the memory device 300′is lower than the memory device 300. In this embodiment, a width GW of each of the gaps X may be within 1 μm. However, this is not a limitation of the present disclosure. The width GW may be adjusted in accordance with the pitch between two adjacent vias on the line segments.

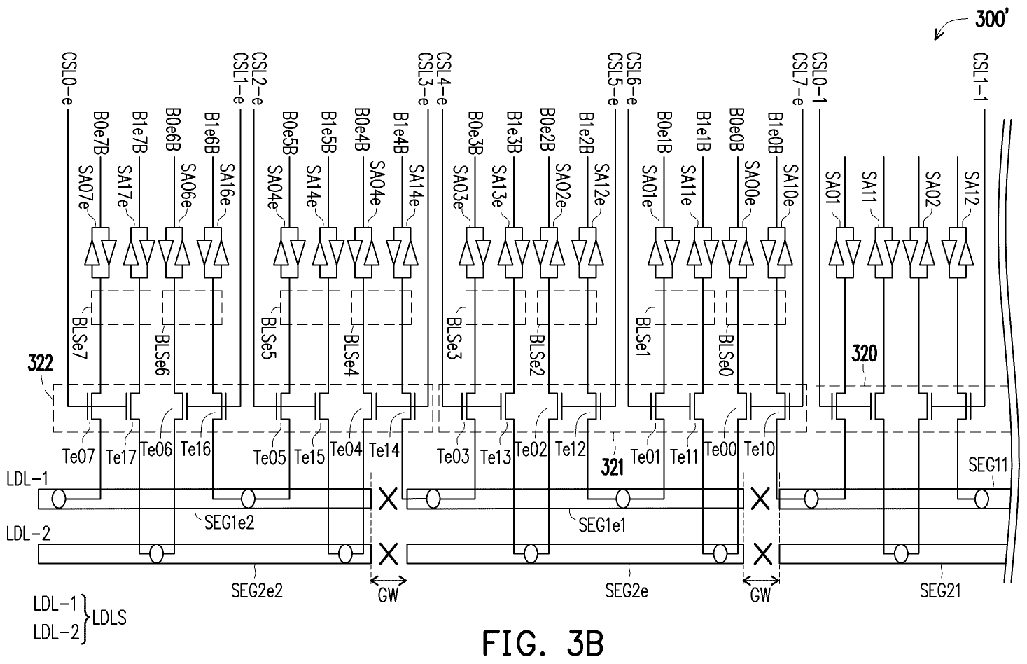

Please refer to FIG. 4, which illustrates a schematic diagram of a portion of a memory device according to an embodiment of present disclosure. In this embodiment, the memory device 400 may include 4 data lines LDL0 to LDL3, and a plurality of bit line groups. Each of the bit line groups are controlled by signals on a plurality of column selection lines CSL0-1˜CLS7-1 to CSL0-5˜CLS7-5. The memory device 400 further includes an extra bit line group which are controlled by control signals on extra column selection line CSL0-e to CSL7-e.

In this embodiment, each of the data lines LDL0 to LDL3 are divided into a plurality of line segments by a plurality of physical gaps GP. In detail, the data line LDL0 is divided into line segments LDL0<0> to LDL0<5>; the data line LDL1 is divided into line segments LDL1<0> to LDL1<5>; the data line LDL2 is divided into line segments LDL2<0> to LDL2<5>; and the data line LDL3 is divided into line segments LDL3<0> to LDL3<5>.

A column selection circuit of the memory device 400 is configured to perform selection operation among bit line sets in the memory device 400 according to the column selection lines CSL0-1˜CLS7-1 to CSL0-5˜CLS7-5, and couples each bit line of each selected bit line set to corresponding segment of one of the data lines LDL0˜LDL3. An extra column selection circuit of the memory device 400 is configured to select one of extra bit line sets according to the extra column selection line CSL0-e to CSL7-e, and to couple each bit line of the selected extra bit line set to the corresponding extra segment of one of the data lines LDL0˜LDL3.

It should be noted here, number of data lines and number of bit line sets can be adjusted by a designer to follow actual need of the memory device. The illustration of FIG. 4 is only an example, and does not limit the scope of present disclosure.

In some embodiments, the gaps for the extra segments may be aligned in the same straight line. In some of the embodiments, the extra gaps may be aligned on same straight line can simplified the design. In some of the embodiments, the gaps which aligns in the same straight line have same width.

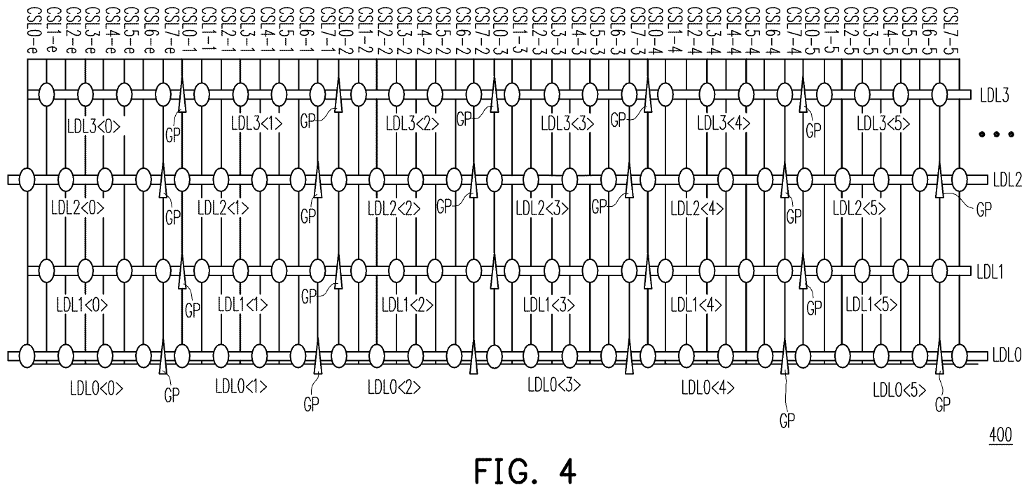

Please refer to FIG. 5, which is a diagram illustrating a portion of a memory device according to an embodiment of present disclosure. There are a main space MSPC and an extended space ECSL of the memory device. The main space MSPC is the normal data input/output (I/O) space of the memory device and the extended space ECSL is the extra storage I/O space in addition to the main space MSPC. In this embodiment, the main space MSPC is configured to have a plurality of I/O pads D0×8˜D3 8 for outputting a normal storage data during a normal data reading operation. The extended space ECSL is disposed in adjacent to the main space, and is configured to have a plurality of extended I/O pads D0˜D3 for outputting an ECC data during an ECC data reading operation, wherein at least one bit of the normal storage data is generated from the extended space during the normal data reading operation. More specifically, the main space MSPC is equally divided into 8 groups of memory space, each group is controlled by 16 column selection lines, i.e. CSL<15:0>. When one column section line is activated, each group may have four I/O pads for outputting the four data bits, i.e. D0 [symbol] D1 [symbol] D2 [symbol] D3, at four data lines respectively. In other words, in each group, the four I/O pads are electrically connected to the four data lines respectively. Therefore, when one column section line is activated, the 8 groups of memory space may output 32 bit-data (i.e. 4 bits*8 groups) from the main space MSPC through 32 I/O pads (i.e. D3*8+D2*8+D0*8+D1*8) respectively. Accordingly, the main space MSPC may have 512 bits (i.e. 4 bits*8 groups*16 CSLs) of memory capacity.

On the other hand, the extended space ECSL is arranged to have four (or more) extra columns of memory space, i.e. a total of 16 bits of memory capacity may be outputted. The four columns are controlled by 4 column selection lines, i.e. CSL<3:0>, respectively. Similarly, when one column section line is activated, each column may output four data bits, i.e. D0 [symbol] D1 [symbol] D2 [symbol] D3, through four I/O pads at four data lines respectively. According to the present disclosure, the data D1 and D3 (i.e. two data bits with label “X” in FIG. 5) controlled by the column selection lines CSL0 are assigned to the normal storage space. The reason has been described in above paragraphs related to FIGS. 2˜4, and the detailed description is omitted here for brevity. Accordingly, there are 14 bits of extra data in the extended space ECSL may be outputted and used by the memory controller to perform ECC operation upon the data outputted from the main space MSPC. For example, by performing SECDED ECC operation on data with 512 bits outputted from the main space MSPC, 10 bits of error correction code may be needed. In the embodiment, the 14 extra bits outputted from the extended space ECSL are enough for performing the SECDED ECC operation upon the data from the main space MSPC.

Moreover, in FIG. 5, in the extended space ECSL, the data D3 that controlled by the extra column selection line CSL1˜CSL3, the data D2 that controlled by the extra column selection line CSL0˜CSL3, the data D1 that controlled by the extra column selection line CSL1˜CSL3, and the data D0 that controlled by the extra column selection line CSL0˜CSL3 may be outputted to the memory controller through 4 different input/output (I/O) pads or vias electrically connected to the four data lines of the extended space ECSL respectively.

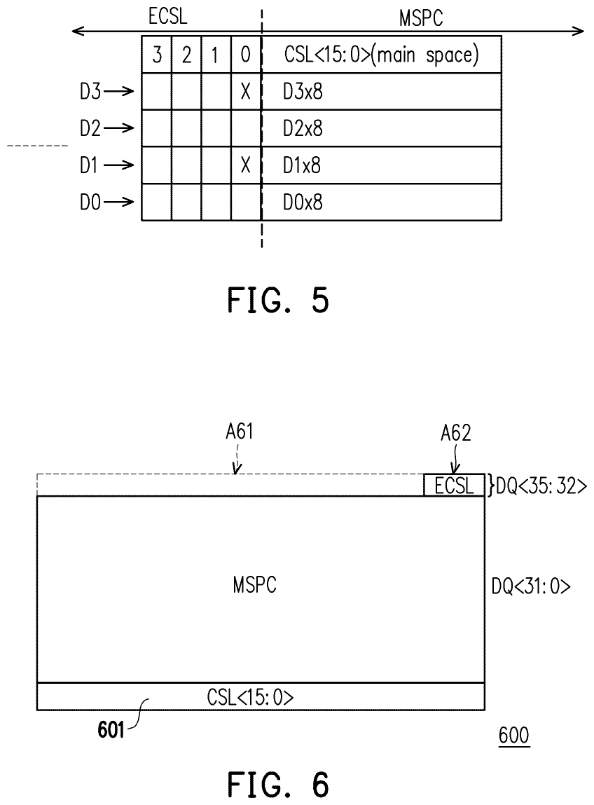

Please refer to FIG. 6, which is a diagram illustrating an arrangement of a memory device 600 according to an embodiment of present disclosure. For brevity, the capacity of memory device 600 is similar to the memory device as shown in FIG. 5. The main space MSPC and the extended space ECSL are controlled by a column selection circuit 601. The main space MSPC is controlled by 16 column selection lines CSL<15:0>, and the extended space ECSL is controlled by 4 column selection lines CSL<3:0>. When one of the column section line CSL<15:0>is activated, 32 bit-data (i.e. DQ<31:0>) is outputted from the main space MSPC. Moreover, when one of the column section line CSL<3:0> is activated, 4 bit-data (i.e. DQ<35:32>) is outputted from the extended space ECSL. It should be noted that when the column section line CSL0 is activated, only 2 bit-data (i.e. D2 & D0) is outputted from the extended space ECSL because the other 2 bit-data (i.e. D3 & D1) are assigned to the main space MSPC, and the detailed description is omitted here for brevity. It can be seen that the size or circuit area A62 of extended space ECSL used for storing the ECC data is smaller than the circuit area (i.e. A61+A62) of existing counterpart of ECC data storing memory. More specifically, for performing an ECC operation on accessing data, in a case for the existing ECC data storing memory, the memory data length may be extended to 36-bit (DQ<35:0>) for corresponding to all of the column selection lines CSL<15:0>, i.e., when one of the column section line CSL<15:0> is activated, 36 bit-data (i.e. DQ<35:0>) may be outputted from the memory space. In other words, the circuit areas A61 and A62 are necessary for the existing memory device. On the contrary, in the present disclosure, only some (e.g. four column selection line CSL<3:0>) of the column selection lines CSL<15:0> are connected to the extended space ECSL to output the extended data DQ<35:32>. Therefore, only the circuit area A62 is required and the circuit area A61 can be saved. Accordingly, the circuit size of the memory device 600 can be reduced. It is noted that, according to the present disclosure, the size or circuit area A62 of the extended space ECSL is smaller than the size of the main space MSPC.

In addition, the memory controller may execute the ECC operation after the data in the main space MSPC are read out. In other words, the memory controller is arranged to read the ECC data in the extended space ECSL after the data in the main space MSPC have been read. Then, the memory controller may use the ECC data in the extended space ECSL to perform ECC operation upon the data in the main space MSPC. For example, the memory controller may control the column selection line CSL0 to read out the corresponding ECC data in the extended space ECSL after the main data bits corresponding to the column selection lines CSL0 in the main space MSPC are already read out.

In some embodiments, the memory capacity of the main space MSPC may be extended to 1024 bits by duplicating the original main space with 512 bits. The original main space and the duplicated main space MSPC share the same SA region, which is also be referred as Open Bit Line architecture. The original main space and the duplicated main space constitute the main space MSPC. Similarly, the extended space ECSL may also be extended to 28 bits by duplicating the original extend space with 14 bits. The original extended space and the duplicated extended space constitute the extended space ECSL. The 28 bits of data in the extend space ECSL may be used for performing the SECDED ECC operation upon the 1024 bits of data in the main space MSPC. It is noted that the SECDED ECC operation is merely an example, those skill in the art may modify the extended space ECSL to have suitable memory capacity depending on different type of ECC operations.

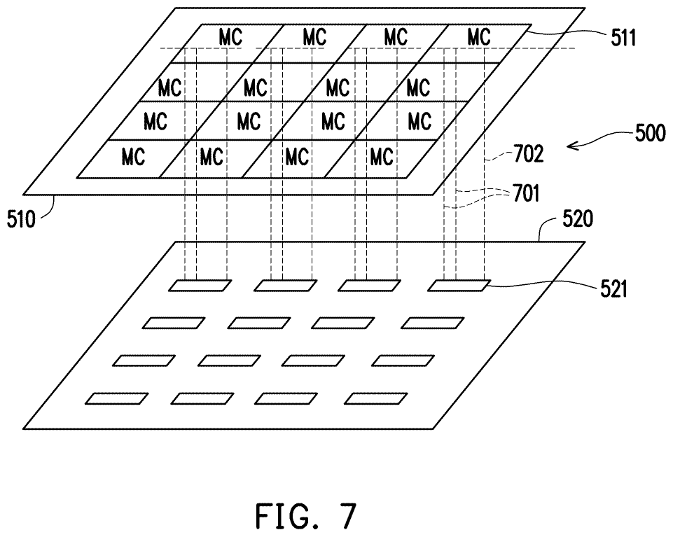

Please refer to FIG. 7, which illustrates a schematic diagram of a semiconductor device according to an embodiment of present application. The semiconductor device 500 may be formed by two chips 510 and 520, where the chips 510 and 520 are electrically stacked with each other. The semiconductor device 500 may be implemented by using wafer-on-wafer (WoW) bonding technology. For example, one of the WoW bonding technologies is the hybrid-bonding technique. For simplicity, the bonding between two chips 510 and 520 is illustrated by the dashed line as shown in FIG. 5.

The chip 510 includes a plurality of memory cell arrays MC, and the memory cell arrays MC form a memory device 511. It should be noted here, the local data line (LDL) may be implemented in the chip 510 with corresponding memory cell array MC. The chip 520 includes a controller which includes a plurality of logic circuits 521. The logic circuits 521 may be respectively integrated with the memory cell arrays MC in the chip 510 by bonding process or other integration method well known by a person skilled in the art. Each of the logic circuits 521 is configured to perform error correction/detection operation of corresponding memory cell array MC. Each of the logic circuits 521 may perform ECC encoding operation or ECC decoding operation. During a data write-in operation, each of the logic circuits 521 may perform ECC encoding operation on a write-in data to generate an error correction code. Each of the logic circuits 521 further write the write-in data and the corresponding error correction code into the corresponding memory cell array MC. During a data readout operation, a stored data and corresponding ECC data may be readout, and each of the logic circuits 521 may perform ECC decoding operation on the readout stored data and the corresponding ECC data to generate a syndrome value. By checking the syndrome value by the logic circuit 521, whether the readout stored data is correct or not can be known, and error bit(s) of the readout stored data can be further correct by the ECC operation. In some embodiments, the control logics may include memory controllers, embedded memory controllers, processors, central processing units (CPU), or graphic processing units (GPU).

In this embodiment, the ECC data may be transferred by the extra bits through the LDL structure mentioned in above embodiment. More specifically, the ECC data may be transferred from the memory cell arrays MC in the chip 510 to the logic circuit 521 through the bonding between two chips 510 and 520. The logic circuit 521 may read the stored data firstly from the corresponding memory cell array MC, read the corresponding ECC data secondly from the corresponding memory cell, and then perform the ECC operation. In some of the embodiments, both of each logic circuit 521 and each memory cell array MC may be laterally placed on a package substrate, such as package board or interposer, rather than vertical stacking on each other.

Please be noted here, each of the memory cell array MC may have its own extra bits, the extra bits for specific one of the memory cell arrays MC is configured to be received as the ECC data for the detection or correction of the specific one of the memory cell arrays MC. In some of the embodiments, the extra bits of the specific one of the memory cell arrays MC is configured to be received as the ECC data for the detection or correction of the another one of the memory cell arrays MC. In some of the embodiments, the extra bits from a plurality of the memory cell arrays MC are configured to group up and be received as the ECC data for the detection or correction of the main bits in the plurality of the memory cell arrays MC.

In some embodiments, a memory device implemented by the semiconductor device 500 may include a memory controller. The memory controller may be disposed in the chip 520. The memory controller may be electrically coupled to the main space MSPC and the extended space ECSL as illustrated in FIG. 6 through the I/O pads 701 and the extended I/O pads 702. The memory controller may receive normal storage data and the ECC data through the I/O pads 701 and the extended I/O pads 702, respectively. Furthermore, in some embodiments, the memory controller may be further arranged to perform ECC operation upon the received normal storage data.

Please be noted here, in some embodiments, the ECC decoder and the ECC encoder may be disposed with the corresponding memory cell MC in the first chip 510. However, it is not limited thereto. In some embodiments, the ECC decoder and the ECC encoder may be disposed in the logic circuit 521 in the second chip 520 corresponding to the memory cell MC in the first chip 510.

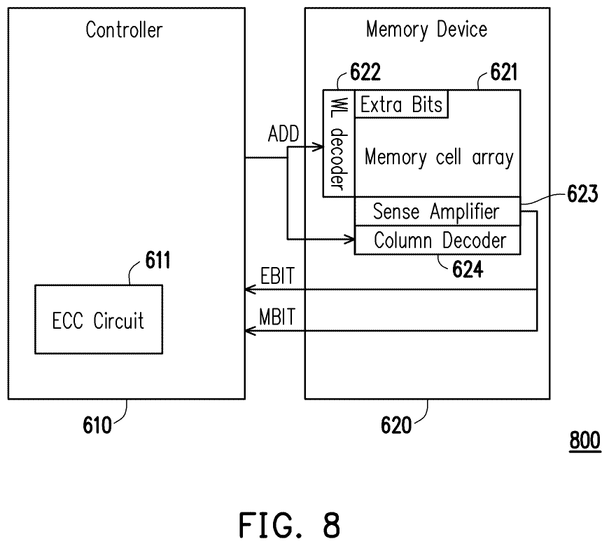

Please refer to FIG. 8, which illustrates a block diagram of a semiconductor device according to an embodiment of present disclosure. The semiconductor device 800 includes a controller 610 and a memory device 620. The controller 610 is electrically coupled to the memory device 620. The controller 610 includes ECC circuit 611 which may be implemented a digital circuit. The ECC circuit 611 is configured to perform an error correction/detection operation based on extra bits transmitted from the memory device 620. The memory device 620 includes a memory cell array 621, word line (WL) decoder 622, sense amplifier 623, column decoder 624. In this embodiment, a first part of the memory cell array 621 may be used to store main bits, and another part of the memory cell array 621 may be used to store the extra bits. The extra bits may be error correction/detection information, such as ECC data. In some embodiments, the memory device 620 may be disposed in the first chip 510, and the controller 610 may be disposed in the second chip 520. In this embodiment, the memory cell array 621 may be a DRAM array.

The controller 610 is coupled to the WL decoder 622 and the column decoder 624, and transmits address information ADD to the WL decoder 622 and the column decoder 624. The WL decoder 622 and the column decoder 624 decode the address information ADD to access the memory cell array 621, and during a data readout operation, the memory cell array 621 may send readout data through the sense amplifier 623 to the controller 610, where the readout data may be the main bits MBIT (or said normal storage data) or the extra bits EBIT as mentioned in previous paragraphs.

The ECC circuit 611 may include a plurality of ECC decoders and ECC encoders. The memory cell array 621 may be divided into a plurality of portions, and the ECC decoders and the ECC encoders may respectively correspond to the portions of the memory cell array 621.

In present disclosure, a large number of I/O counts can be achieved by the segmentation of the local data line {LDL} and the extra bit line sets as illustrated in FIG. 1. In some embodiments, the number of the I/O counts may be more than 10,000. In some embodiments, the number of the I/O counts may be more than 500,000. Therefore, an high bandwidth operation can be achieved on the memory device through the large number of the I/O counts.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a first bit line set, comprising a first bit line and a second bit line;
a first column selection circuit, coupled to the first bit line and the second bit line;
a first data line, comprising a first line segment coupled to the first column selection circuit; and
a second data line, comprising a second line segment coupled to the first column selection circuit;
wherein the first column selection circuit is configured to electrically connect the first bit line to the first line segment for transmitting a first bit of normal data to the first line segment, and to electrically connect the second bit line to the second line segment for transmitting a first bit of Error Correction/Detection data to the second line segment.

2. The memory device according to claim 1, further comprising:
a first via, arranged to electrically couple to the first line segment;
a second via, arranged to electrically couple to the second line segment;
a memory controller, arranged to electrically couple to the first via and the second via for receiving the first bit of normal data and the first bit of ECC data during a normal data reading operation and a ECC data reading operation respectively.

3. The memory device according to claim 2, wherein the memory controller performs the ECC data reading operation after the normal data reading operation.

4. The memory device according to claim 2, wherein the first data line further comprises a third line segment, and the memory device further comprises:
a second bit line set, comprising a third bit line and a fourth bit line;
a second column selection circuit, coupled to the third bit line and the fourth bit line;
wherein the second column selection circuit is configured to electrically connect the third bit line to the third line segment for transmitting a second bit of ECC data to the third line segment, and to electrically connect the fourth bit line to the second line segment for transmitting a third bit of ECC data to the second line segment.

5. The memory device according to claim 4, further comprising:
a third via, arranged to electrically couple to the third line segment;
wherein the memory controller is further arranged to receive the second bit of ECC data through the third via and to receive the third bit of ECC data through the second via during the ECC data reading operation.

6. The memory device according to claim 4, wherein the first line segment and the third line segment are separated by a first gap.

7. The memory device according to claim 6, wherein the second data line further comprises a fourth line segment, and the memory device further comprises:
a third bit line set, comprising a fifth bit line and a sixth bit line;
a third column selection circuit, coupled to the fifth bit line and the sixth bit line;
wherein the third column selection circuit is configured to electrically connect the fifth bit line to the first line segment for transmitting a second bit of normal data to the first line segment, and to electrically connect the sixth bit line to the fourth line segment for transmitting a third bit of normal data to the fourth line segment, the second line segment and the fourth line segment are separated by a second gap, and the first gap and the second gap form a first straight line and the first straight line is perpendicular to the first data line and the second data line.

8. The memory device according to claim 7, wherein the first data line further comprises a fifth line segment and the second data line further comprises a sixth line segment, and the memory device further comprises:
a fourth bit line set, comprising a seventh bit line and an eighth bit line;
a fourth column selection circuit, coupled to the seventh bit line and the eighth bit line;
wherein the fourth column selection circuit is configured to electrically connect the seventh bit line to the fifth line segment for transmitting a fourth bit of ECC data to the fifth line segment, and to electrically connect the eighth bit line to the sixth line segment for transmitting a fifth bit of ECC data to the sixth line segment, the third line segment and the fifth line segment are separated by a third gap, the second line segment and the sixth line segment are separated by a fourth gap, and the third gap and the fourth gap form a second straight line and the second straight line is perpendicular to the first data line and the second data line.

9. The memory device according to claim 8, further comprising:
a fifth bit line set, comprising a ninth bit line and a tenth bit line;
a fifth column selection circuit, coupled to the ninth bit line and the tenth bit line;
wherein the fifth column selection circuit is configured to electrically connect the ninth bit line to the third line segment for transmitting a sixth bit of ECC data to the third line segment, and to electrically connect the tenth bit line to the sixth line segment for transmitting a seventh bit (B0e4B) of ECC data to the sixth line segment.

10. The memory device according to claim 9, further comprising:
a fourth via, arranged to electrically couple to the third line segment;
a fifth via, arranged to electrically couple to the sixth line segment;
wherein the memory controller is further arranged to electrically couple to the fourth via and the fifth via for receiving the sixth bit of ECC data and the seventh bit of ECC data during the ECC data reading operation.

11. A memory device, comprising:
a plurality of memory cell arrays; and
a plurality of data sensing circuitry areas, wherein each of the data sensing circuitry areas is disposed between two of the adjacent memory cell arrays, each of the data sensing circuitry areas comprises:
a main space, having a plurality of I/O pads for outputting a normal storage data during a normal data reading operation; and
an extended space, disposed in adjacent to the main space, and having a plurality of extended I/O pads for outputting an ECC data during an ECC data reading operation;
wherein at least a first bit of the normal storage data is generated from the extended space during the normal data reading operation.

12. The memory device according to claim 11, wherein a size of the extended space is smaller than a size of the main space.

13. The memory device according to claim 11, further comprising:
a memory controller, electrically coupled to the main space and the extended space through the I/O pads and the extended I/O pads for receiving the normal storage data and the ECC data;
wherein the memory controller is further arranged to perform an ECC operation upon the normal storage data.

14. The memory device according to claim 13, wherein the main space and the extended space are formed in a first chip of a first semiconductor wafer, the memory controller is formed in a second chip of a second semiconductor wafer, and the memory controller is bonded to the main space and the extended space through the I/O pads and the extended I/O pads.

15. The memory device according to claim 11, wherein each of the data sensing circuitry areas further comprises:
a column selection circuit, arranged to control the main space and the extended space to output the normal storage data during the normal data reading operation, and arranged to control the extended space to output the ECC data during the ECC data reading operation after the normal data reading operation.

16. The memory device according to claim 11, wherein the main space comprises a first line segment, the extended space comprises:
a first bit line set, comprising a first bit line and a second bit line;
a first column selection circuit, coupled to the first bit line and the second bit line;
a second line segment, coupled to the first column selection circuit;
wherein the first column selection circuit is configured to electrically connect the first bit line to the first line segment for transmitting the first bit of normal data to the first line segment, and to electrically connect the second bit line to the second line segment for transmitting a first bit of ECC data to the second line segment.

17. The memory device according to claim 16, wherein the main space further comprises a first via arranged to electrically couple to the first line segment, the extended space further comprises a second via arranged to electrically couple to the second line segment, and the memory device further comprises:
a memory controller, arranged to electrically couple to the first via and the second via for receiving the first bit of normal data and the first bit of ECC data during the normal data reading operation and the ECC data reading operation respectively.

18. The memory device according to claim 16, wherein the extended space further comprises:
a third line segment;
a second bit line set, comprising a third bit line and a fourth bit line;
a second column selection circuit, coupled to the third bit line and the fourth bit line;
wherein the second column selection circuit is configured to electrically connect the third bit line to the third line segment for transmitting a second bit of ECC data to the third line segment, and to electrically connect the fourth bit line to the second line segment for transmitting a third bit of ECC data to the second line segment.

19. The memory device according to claim 18, wherein the first line segment and the third line segment are separated by a first gap.

20. The memory device according to claim 19, wherein the main space further comprises:
a fourth line segment;
a third bit line set, comprising a fifth bit line and a sixth bit line;
a third column selection circuit, coupled to the fifth bit line and the sixth bit line;
wherein the third column selection circuit is configured to electrically connect the fifth bit line to the first line segment for transmitting a second bit of normal data to the first line segment, and to electrically connect the sixth bit line to the fourth line segment for transmitting a third bit of normal data to the fourth line segment, the second line segment and the fourth line segment are separated by a second gap, and the first gap and the second gap form a first straight line and the first straight line is perpendicular to the first data line and the second data line.
